(19) United States
(12) Patent Application Publication
(10) Pub. No.: US 2026/0245831 A1
(43) Pub. Date: Aug. 20, 2026

(54) STRUCTURAL MEMBER

(71) Applicant: TOTO LTD., Fukuoka (JP)

(72) Inventors: Kenichi MOTOMURA, Fukuoka (JP); Ryoto TAKIZAWA, Fukuoka (JP)

(73) Assignee: TOTO LTD., Fukuoka (JP)

(21) Appl. No.: 19/539,418

(22) Filed: Feb. 13, 2026

(30) Foreign Application Priority Data
Feb. 17, 2025 (JP) 2025023720

(51) Int. Cl. H01J 37/32

(52) U.S. Cl. CPC H01J 37/321

(57) ABSTRACT

The structural member 10 includes a base material 100 and a protective film 200 including yttria as a main component, the protective film 200 covering the surface 110 of the base material 100. In a diffraction pattern obtained by analyzing the surface 210 of the protective film 200 using X-ray diffraction, when a particle diameter calculated based on a profile of a peak attributed to the (222) plane of a cubic crystal structure is defined as D1, and a particle diameter calculated based on a profile of a peak attributed to the (622) plane of a cubic crystal structure is defined as D2, the structural member has an average value of D1 and D2 of 90 Å or more.

### CROSS-REFERENCE TO RELATED APPLICATION

This application is based upon and claims the benefit of priority from Japanese Patent Application No. 2025-023720 filed on Feb. 17, 2025, the entire contents of which are incorporated herein by reference.

### FIELD

The present invention relates to a structural member.

### BACKGROUND

Durability against plasma is required for members constituting a semiconductor manufacturing apparatus, for example, members such as chamber inner walls and the like. Therefore, structural members having a protective film formed on the surface of a base material have been commonly used as the above members as disclosed in Japanese Patent Laid-Open No. 2007-321183. Materials, such as yttria, are often used as protective films.

### SUMMARY

When base materials are repeatedly processed in a semiconductor manufacturing apparatus, the protective film degrades gradually over time. To reduce the frequency of maintenance for a semiconductor manufacturing apparatus, it is desirable that the protective film has a durability against plasma as high as possible.

The present invention has been made in view of such problems, and an object of the present invention is to provide a structural member comprising a protective film having high durability against plasma.

To solve the above problem, the structural member of the present invention comprises a base material and a protective film comprising yttria as a main component, the protective film covering the surface of the base material. In a diffraction pattern obtained by analyzing the surface of the protective film using X-ray diffraction, when a particle diameter calculated based on a profile of a peak attributed to the (222) plane of a cubic crystal structure is defined as D1, and a particle diameter calculated based on a profile of a peak attributed to the (622) plane of a cubic crystal structure is defined as D2, the structural member has an average value of D1 and D2 of 90 Å or more.

The experiments conducted by the present inventors have demonstrated that by forming the protective film containing yttria as a main component such that the average value of D1 and D2 is 90 Å or more, durability of the protective film against plasma is sufficiently improved.

According to the present invention, a structural member with sufficient durability against plasma can be provided.

### BRIEF DESCRIPTION OF THE DRAWINGS

FIG. 1 schematically illustrates a cross-section of the structural member;

FIG. 2 is a graph illustrating the relationship between the average particle diameter of the protective film and the durability of the protective film against plasma;

FIG. 3 is a graph illustrating an analytical method using X-ray diffraction;

FIG. 4 is a graph illustrating an analytical method using X-ray diffraction;

FIG. 5 is a graph illustrating an analytical method using X-ray diffraction;

FIG. 6 is a graph illustrating an analytical method using X-ray diffraction; and

FIG. 7 is a table listing film-forming conditions and the like when forming a protective film.

### DETAILED DESCRIPTION

Hereinafter the present embodiment will be described with reference to attached drawings. For clarity of description, identical reference numerals are used to denote the same elements in all figures, and redundant descriptions are omitted.

The structural member 10 of the present embodiment is configured as a member for a semiconductor manufacturing apparatus, such as a plasma etching apparatus. More specifically, the structural member 10 is a member used for the inner wall of a process chamber of semiconductor manufacturing apparatus. The use of the structural member 10 in the present embodiment is merely an example. The structural member 10 may be a member arranged within the process chamber of semiconductor manufacturing apparatus, such as a focus ring.

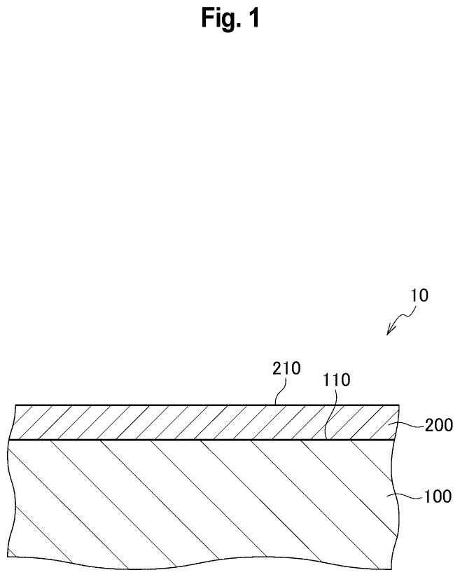

As shown in FIG. 1, the structural member 10 includes a base material 100 and a protective film 200. In a plasma etching apparatus or the like, the surface 210 of the protective film 200 is exposed to the interior of the process chamber. The protective film 200 is formed to protect the surface 110 of the base material 100 from plasma.

The base material 100 is a member forming the primary portion of the structural member 10. In the present embodiment, the base material 100 is a sintered ceramic body including high-purity alumina (Al₂O₃) as a main component, but may be a different ceramic material or member other than a non-ceramic material (for example, a metal member). The surface 110 of the base material 100 is flat in the present embodiment, but may be curved or tapered in portions.

The protective film 200 is formed to protect the base material 100 from plasma as described above. The protective film 200 is formed to cover the entire surface 110 of the base material 100. The protective film 200 is composed of a material including yttria (Y₂O₃) as a main component. The ratio between the number of yttrium (Y) atoms and the number of oxygen (O) atoms in the protective film 200 may be different from the ratio described above. The protective film 200 of the present embodiment is formed by using a physical vapor deposition (PVD) method, but may be formed by another film-forming method.

As used herein, the “main component” refers to the compound contained in the greatest amount in the target object (for example, protective film 200). More specifically, the “main component” refers to the compound contained in the greatest amount in terms of volume ratio or mass ratio relative to other compounds in the object, as determined by quantitative or semi-quantitative analysis using X-ray diffraction (XRD) on the object.

The proportion of the main component (yttria) in the protective film 200 of the present embodiment is more than 50% by volume or by mass. The proportion may be more than 70%, more than 90%, or may be 100%.

The thickness of the protective film 200 is appropriately adjusted depending on the duration for which durability is required to be maintained and other factors. In the present embodiment, the protective film 200 has a thickness of 15 μm or less.

The present inventors have used yttria as a material for the protective film 200 as in the present embodiment, and have been considering further improvement in the durability of the material against plasma. As a result, it has been confirmed that when the protective film 200 is formed using a material comprising yttria as a main component, the durability of the protective film 200 against plasma varies depending on the crystal structure of the protective film 200. Specifically, it has been confirmed that in a diffraction pattern obtained by analyzing the surface 210 using X-ray diffraction, when a particle diameter calculated based on a profile of a peak attributed to the (222) plane of a cubic crystal structure is defined as “particle diameter D1”, a particle diameter calculated based on a profile of a peak attributed to the (622) plane of a cubic crystal structure is defined as “particle diameter D2”, and the average value of the particle diameter D1 and the particle diameter D2 is defined as an “average particle diameter”, the larger the average particle diameter, the higher the durability of the protective film 200 against plasma. The specific method for calculating the above particle diameters will be described later.

The present inventors prepared multiple samples of the structural member 10 with varying crystal structures for the protective film 200, and assessed durability against plasma for each protective film 200. To evaluate the durability of the protective film 200 against plasma, the surface 210 of each protective film 200 was exposed to a plasma environment using an inductively coupling plasma reactive ion etching (ICP-RIE) system (not shown). The surface 210 was exposed to a plasma atmosphere by the following method.

First, a 4-inch silicon wafer was held by an electrostatic chuck within the chamber of an inductively coupled plasma reactive ion etching system. A sample of the structural member 10, the subject of evaluation, was placed on the silicon wafer. Subsequently, the surface 210 of the protective film 200 was exposed to a plasma environment by generating plasma within the chamber. SF₆ was used as the process gas, and supplied to the chamber at a flow rate of 100 sccm. The pressure in the chamber was adjusted to 0.5 Pa. The time of exposure was 60 minutes. The power output was set to 1,500 W for the ICP coil, and the bias output was turned off (i.e., 0 W). The plasma exposure test for the surface 210 of the protective film 200, performed under the conditions described above, is called the “Standard Plasma Test” below. In the Standard Plasma Test, by turning off the bias output as described above, the plasma is not drawn toward the protective film 200, and hardly used for the etching of the protective film 200. The surface 210 of the protective film 200 is simply exposed to non-directional plasma.

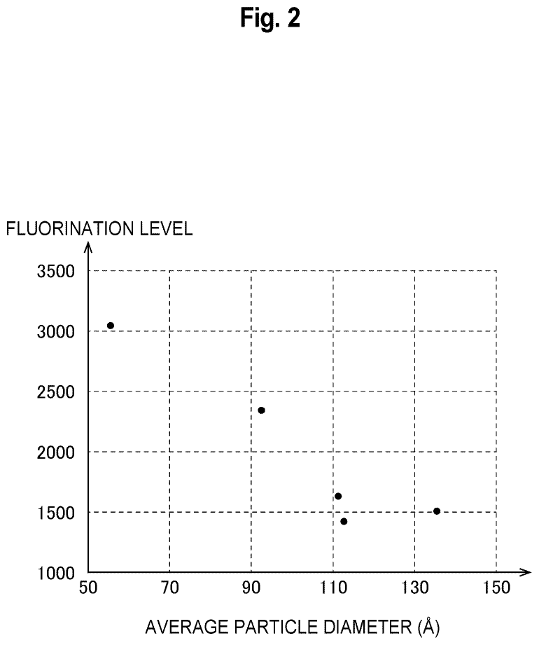

FIG. 2 shows the results of the Standard Plasma Test described above conducted for each of the structural members 10. The horizontal axis of the graph in FIG. 2 represents the above-described average particle diameter. The vertical axis represents the fluorination level of the protective film 200 after conducting the Standard Plasma Test. The “fluorination level” is an indicator of how deep fluorine atoms, which are part of plasma, penetrate into the interior of the protective film 200. Specific measurement methods of the fluorination level are as follows.

First, while sputtering the surface 210 of the protective film 200 after the Standard Plasma Test using argon, the amount of fluorine atoms present on the surface 210 was continuously measured by X-ray photoelectron spectroscopy (XPS). The measurement was performed for 145 seconds. During the measurement, the proportion of the measured argon concentration in the overall composition (in %) was calculated at each time point, and the integrated value of these proportions was defined as the “fluorination level” of the sample. The higher the durability of the protective film 200 against plasma, the smaller the value of the fluorination level calculated as described above. The fluorination level may be used as an indicator of the durability of the protective film 200 against plasma.

As FIG. 2 clearly shows, the larger the average particle diameter of the protective film 200, the substantially smaller the fluorination level of the protective film 200. For the protective film 200 having an average particle diameter of 90 Å or more, the fluorination level is as low as less than 2,500, and sufficient resistance to plasma was verified.

The calculation method of the average particle diameter will be described. The average particle diameter is calculated from the results of the analysis of the crystal structure of the protective film 200 using X-ray diffraction.

For each sample, the average particle diameter of the protective film 200 was measured using the following method. First, grazing-incidence X-ray diffraction (GIXRD) was performed on the protective film 200 formed on the base material 100 by out-of-plane measurement.

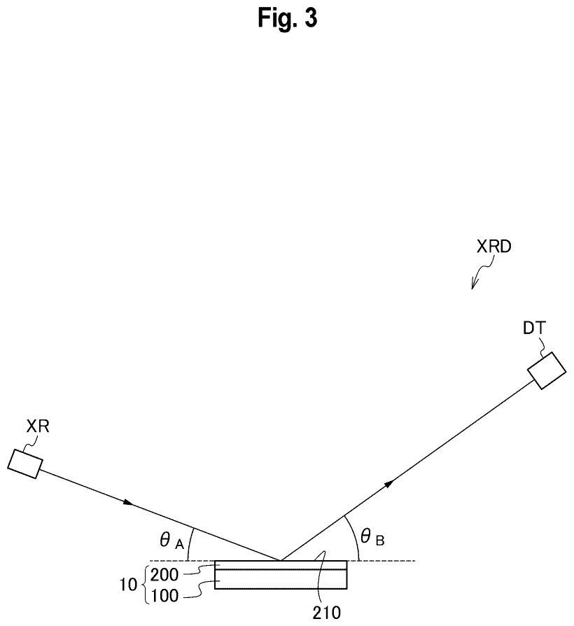

X-ray diffraction was performed using an X-ray diffraction apparatus XRD, as shown in FIG. 3. In the X-ray diffraction apparatus XRD, X-rays of a specific wavelength generated by the X-ray source XR are directed onto the surface 210 of the protective film 200, which is the measurement target. The intensity distribution obtained by detecting the scattered light generated at the surface 210 with the detector DT, i.e., the intensity distribution of the scattered light with respect to the diffraction angle θ_{B} (diffraction pattern), corresponds to the crystal structure of the protective film 200. Here, as the incident angle θ_{A} of the X-rays relative to the surface 210 increases, the obtained diffraction pattern corresponds to the crystal structure at deeper positions from the surface 210. In other words, by performing X-ray diffraction while varying the incident angle θ_{A}, the crystal structure at any depth within the protective film 200 can be investigated.

In this embodiment, “SmartLab” manufactured by Rigaku was used as the X-ray diffraction apparatus XRD. The tube voltage was set to 45 kV, the tube current to 200 mA, the scan range to 18 to 80°, the step size to 0.05°, the scan speed to 0.5°/min, and the X-ray incident angle θ_{A} to 0.3°. The sample size was approximately 20 mm×20 mm.

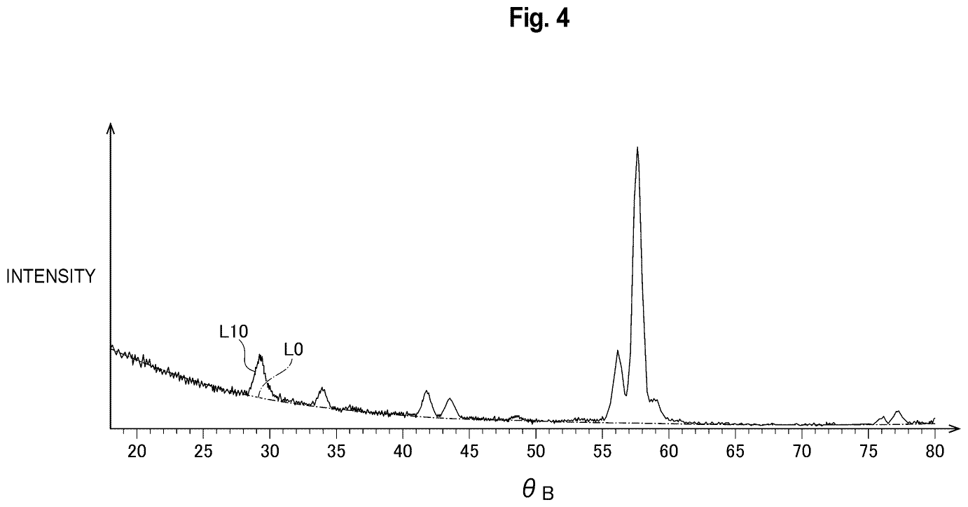

The line L10 in FIG. 4 is an example of the diffraction patterns obtained by analyzing the protective films 200 using X-ray diffraction as described above. This diffraction pattern is also referred to as “the measured diffraction pattern L10” below. A plurality of peaks are observed in the measured diffraction pattern L10, and the profile of each peak corresponds to the crystal structure of the material of the protective film 200. For example, the diffraction angles θ_{B} corresponding to the maximum of each peak are characteristic of the crystal structure of the protective film 200. The height of each peak corresponds to the proportion of the crystal structure associated with the diffraction angle θ_{B} in the surface (210) of the protective film 200.

The dash-dotted line L0 shown in FIG. 4 represents the background intensity in the absence of peaks. The profile of the dash-dotted line L0 can be inferred, for example, from the overall diffraction pattern.

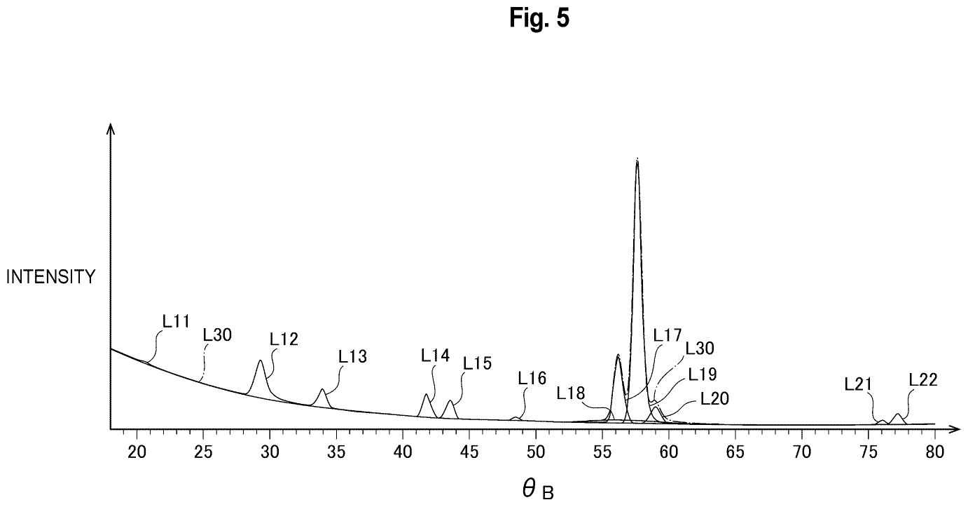

The line L11 shown in FIG. 5 represents a hypothetical diffraction pattern obtained by adding only the peak with the maximum at a diffraction angle θ_{B} of 20.72° to the background represented by the dash-dotted line L0 in FIG. 4. The same applies to the lines L12 to L22 shown in FIG. 5, each line representing a hypothetical diffraction pattern obtained by adding only the peak with the maximum at a specific diffraction angle θ_{B} to the background.

The diffraction angle θ_{B} of the peak of line L12 is 29.23°; the diffraction angle θ_{B} of the peak of line L13 is 33.89°; the diffraction angle θ_{B} of the peak of line L14 is 41.70°; the diffraction angle θ_{B} of the peak of line L15 is 43.50°; the diffraction angle θ_{B} of the peak of line L16 is 48.41°; the diffraction angle θ_{B} of the peak of line L17 is 56.10°; the diffraction angle θ_{B} of the peak of line L18 is 56.70°; the diffraction angle θ_{B} of the peak of line L19 is 57.54°; the diffraction angle θ_{B} of the peak of line L20 is 58.83°; the diffraction angle θ_{B} of the peak of line L21 is 76.04°; and the diffraction angle θ_{B} of the peak of line L22 is 77.11°.

The dash-dotted line 30 shown in FIG. 5 is a diffraction pattern obtained by combining all the hypothetical diffraction patterns represented by the lines L11 to L22. This diffraction pattern is also referred to as “approximated diffraction pattern L30” below. When combining multiple hypothetical diffraction patterns, redundant background intensities are not added.

The hypothetical diffraction patterns represented by the lines L11 to L22 are individually adjusted so that the profile of the approximated diffraction pattern L30 obtained by combining them substantially matches the measured diffraction pattern L10 shown in FIG. 4. In other words, by individually adjusting the diffraction angle θ_{B} at which the peak reaches the maximum and the height of the peak relative to the background for each line such as L11, the profile of the approximated diffraction pattern L30 is brought closer to the measured diffraction pattern L10. When the two profiles substantially match as a result of such adjustments, each hypothetical diffraction pattern represented by the lines L11 to L22 corresponds to a profile decomposed from the measured diffraction pattern L10 at each diffraction angle θ_{B}. Such a process may be performed manually while observing the profile of the approximated diffraction pattern L30, or may be performed automatically using the software functionality.

When the material of the protective film 200 is yttria, the diffraction angle θ_{B} of the peak attributed to the (222) plane of the cubic crystal structure is known to be approximately 29.15°. Thus, in the example shown in FIG. 5, the peak attributed to the (222) plane of the cubic crystal structure can be inferred as the peak represented by the line L12.

When the material of the protective film 200 is yttria, the diffraction angle θ_{B} of the peak attributed to the (622) plane of the cubic crystal structure is known to be approximately 57.62°. Thus, in the example shown in FIG. 5, the peak attributed to the (622) plane of the cubic crystal structure can be inferred as the peak represented by the line L19.

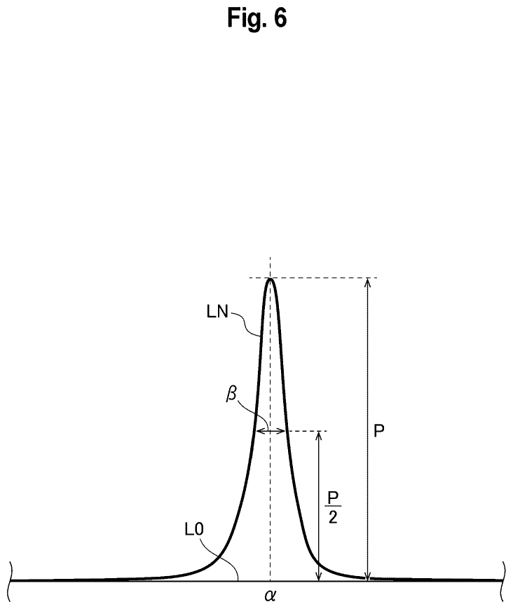

“LN” shown in FIG. 6 is obtained by extracting one peak from lines such as L12 and then modifying the extracted peak so that the dash-dotted line L0 representing the background becomes a flat line. “α” in the same figure is calculated by multiplying a diffraction angle θB at which the peak reaches a maximum by ½. “β” is a so-called full width at half maximum of the peak. That is, when a maximum value of the peak is P, β represents the width of the peak at a height of P/2, expressed in terms of the diffraction angle θB. The profile indicated by line LN, as well as values of α and β corresponding to the profile can be obtained for each of lines such as line L12 and line L19.

The Scherrer equation is known as a method for determining the particle diameter (D) of crystallites corresponding to each peak, such as those shown by line L12, based on the profile of the peaks. The Scherrer equation is expressed as the following equation (1).

### [Equation 1]

“K” on the right-hand side of the equation (1) is a Scherrer constant indicating the shape factor, which is set to 0.94 in the present embodiment. “λ” represents the wavelength of X-rays with which the surface 210 is irradiated, in units of Å, which is set to 1.5418 Å in the present embodiment. “α” and “β” are the α and β described with reference to FIG. 6. β is expressed in degrees.

For example, for the profile of the peak of line L12, α and β shown in FIG. 6 are calculated, and the particle diameter (D) can be calculated using these values and the equation (1). The particle diameter thus calculated can be regarded as the particle diameter calculated based on the profile of a peak attributed to the (222) plane of a cubic crystal structure. This particle diameter is hereinafter also referred to as “particle diameter D1”.

Similarly, for the profile of the peak of line L19, α and β shown in FIG. 6 are calculated, and the particle diameter (D) can be calculated using these values and equation (1). The particle diameter thus calculated can be regarded as the particle diameter calculated based on the profile of a peak attributed to the (622) plane of a cubic crystal structure. This particle diameter is hereinafter also referred to as “particle diameter D2”.

The “average particle diameter” shown in FIG. 2 is an average value of the particle diameter D1 and the particle diameter D2 calculated as described above. As previously stated, for the protective film 200 having an average particle diameter of 90 Å or more, the fluorination level is as low as less than 2,500, and sufficient resistance to plasma was verified. In other words, by forming a protective film 200 such that the average particle diameter is 90 Å or more, a protective film 200 having high durability against plasma can be obtained.

The patterns shown in FIGS. 4, 5, and 6 are examples for illustrating the definition and the calculation method of the average particle diameter, and do not correspond to the protective film 200 of the present embodiment.

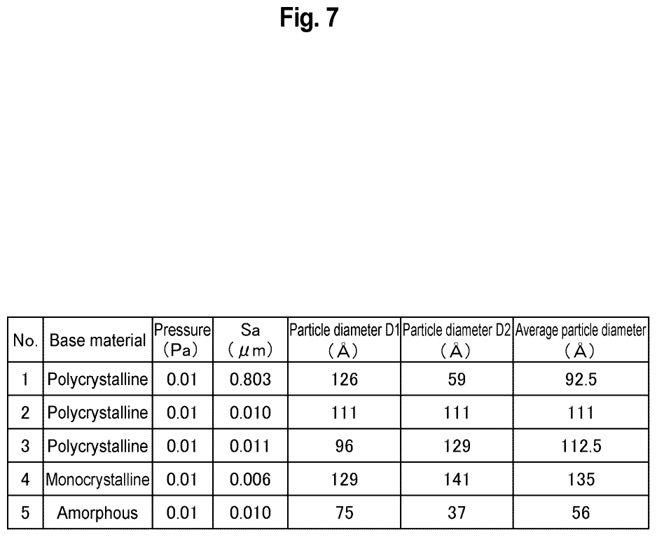

The method and other conditions for producing the samples used for obtaining the data shown in FIG. 2 will be described with reference to FIG. 7. Sample No. 1 in FIG. 7 is a sample prepared under conditions such that the average particle diameter on the surface 210 of the protective film 200 is 92.5 Å; Sample No. 2 is a sample prepared under conditions such that the average particle diameter on the surface 210 of the protective film 200 is 111 Å; Sample No. 3 is a sample prepared under conditions such that the average particle diameter on the surface 210 of the protective film 200 is 112.5 Å; Sample No. 4 is a sample prepared under conditions such that the average particle diameter on the surface 210 of the protective film 200 is 135 Å; and Sample No. 5 is a sample prepared under conditions such that the average particle diameter on the surface 210 of the protective film 200 is 56 Å.

The “Base material” column in the table shown in FIG. 7 shows the structure of the surface 110 of the base material 100, which is made of alumina. In Samples No. 1 to No. 3, the surface 110 of the base material 100 is polycrystalline. In Sample No. 4, the surface 110 of the base material 100 is monocrystalline. In Sample No. 5, the surface 110 of the base material 100 is amorphous.

The protective films 200 of Samples No. 1 to 5 were all formed by a physical vapor deposition (PVD) method. The “Pressure” column shown in the table of FIG. 7 represents the pressure in the film forming chamber during the formation of the protective film 200, in particular, the pressure of argon, in units of Pa.

The “Sa” column shown in the table of FIG. 7 represents the arithmetic mean height (Sa) of the surface 110 immediately before the protective film 200 is formed, in units of μm.

As shown in FIG. 7, Samples No. 1 to 5 differ from one another in terms of the structure and the arithmetic mean height of the surface 110 of the base material 100, and the film-forming conditions for the protective film 200 (specifically, pressures in the film forming chamber), resulting in distinct average particle diameters of the protective film 200.

The particle diameter D1, particle diameter D2, and average particle diameter of Samples No. 1 to No. 5 were calculated. The values obtained are as shown in FIG. 7. Thereafter, the Standard Plasma Test was conducted for each sample, yielding the results shown in FIG. 2. As described with reference to FIG. 2, it has been confirmed that, for Samples No. 1 to No. 4 in which the average particle diameter of the protective film 200 was 90 Å or more, the fluorine level was less than 2,500, and the durability of the protective film 200 against plasma was sufficiently high. it has been confirmed that, for Sample No. 5 in which the average particle diameter of the protective film 200 was less than 90 Å, the fluorine level exceeded 3,000, and the durability of the protective film 200 against plasma was insufficient.

The present inventors have also demonstrated that even when the average particle diameter of the protective film 200 is 90 Å or more, if either one of the particle diameter D1 and particle diameter D2 is less than 50 Å, the durability of the protective film 200 against plasma may be insufficient. Therefore, it is preferable to form a protective film 200 such that the smaller of the particle diameter D1 and the particle diameter D2 is 50 Å or more.

The present embodiment has been described with reference to examples. However, the present disclosure is not limited to these examples. Modifications made to the foregoing examples by those skilled in the art fall within the scope of the present disclosure, provided that they retain the characteristics of the present disclosure. The elements of the foregoing examples, including their configurations, conditions, shapes, and the like, are not limited to those illustrated and can be modified as appropriate. The elements of the foregoing examples can be variously combined, provided that no technical contradiction arises.

What is claimed is:

1. A structural member comprising:
a base material; and
a protective film comprising yttria as a main component, the protective film covering the surface of the base material, wherein,
in a diffraction pattern obtained by analyzing the surface of the protective film using X-ray diffraction,
when a particle diameter calculated based on a profile of a peak attributed to the (222) plane of a cubic crystal structure is defined as D1, and a particle diameter calculated based on a profile of a peak attributed to the (622) plane of a cubic crystal structure is defined as D2, the structural member has an average value of the D1 and the D2 of 90 Å or more.

2. The structural member according to claim 1, wherein the smaller of the D1 and the D2 is 50 Å or more.

3. The structural member according to claim 1, wherein the protective film is formed by using a physical vapor deposition method.

4. The structural member according to claim 1, wherein the base material comprises alumina as a main component.
